(19) United States
(12) Patent Application Publication
(10) Pub. No.: US 2006/0131636 A1
(43) Pub. Date: Jun. 22, 2006

(54) Non-volatile memory device having improved erase efficiency and method of manufacturing the same

(75) Inventors: Sang-hun Jeon, Seoul (KR); Chung-woo Kim, Gyeonggi-do (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Gyeonggi-do (KR)

(21) Appl. No.: 11/249,396

(22) Filed: Oct. 14, 2005

(30) Foreign Application Priority Data
Dec. 16, 2004 (KR) 10-2004-0107160

(51) Int. Cl. H01L 29/788

(52) U.S. Cl. 257/315

(57) ABSTRACT

A non-volatile memory device having an improved erase efficiency and a method of manufacturing the same are provided. The method includes: forming a stack structure of a tunnel dielectric layer, a charge trapping layer, a charge blocking layer and a gate on a semiconductor substrate; and performing a post treatment of the gate using an oxygen or CF₄ plasma or ion implantation to increase a work function of an element forming the gate. Since the work function of the metal layer forming the gate can be further increased, an electron back tunneling can be suppressed during an erase operation.

### CROSS-REFERENCE TO RELATED PATENT APPLICATION

This application claims the benefit of Korean Patent Application No. 10-2004-0107160, filed on Dec. 16, 2004, in the Korean Intellectual Property Office, the disclosure of which is incorporated herein in its entirety by reference.

### BACKGROUND OF THE INVENTION

1. Field of the Invention

Embodiments of the present invention relate to a semiconductor device, and more particularly, to a non-volatile memory device having an improved erase efficiency and a method of manufacturing the same.

2. Description of the Related Art

Non-volatile memory devices can be understood to have a characteristic retaining data even after a power supply is stopped. These non-volatile memory devices have a charge trapping layer by which charges are trapped by and are formed between a gate and a channel of a transistor so as to realize a threshold voltage difference of the channel. The threshold voltage Vₜₕ is varied depending on whether the non-volatile memory devices is in a program state that charges are injected or in an erase state that electrons are erased and accordingly a gate voltage Vg for turning on the channel is varied. Thus, operations of the non-volatile memory device are realized by the concept that the threshold voltage Vₜₕ is varied by charges trapped in or stored in the charge trapping layer.

In a typical flash memory device, a polysilicon floating gate using a metal layer or a metal-like layer has been used as the charge trapping layer. Also, in a silicon-oxide-nitride-oxide-silicon (SONOS) device, a charge trapping site in the silicon nitride is used as the charge trapping layer.

Among trials to improve the characteristics of the non-volatile memory device, endeavors to improve the erase efficiency have been particularly frequently performed. In particular, in spite of a variety of advantages, the SONOS flash memory device faces the task of solving the electron back tunneling issue during an erase operation. As a design rule of the non-volatile memory device decreases substantially, it is more important to improve the erase efficiency. To improve the erase efficiency, it is necessary to preferentially consider improving the electron back tunneling issue which considerably contributes to degradation of the erase efficiency.

The erase operation is generally performed by applying a negative gate voltage Vg lower than 0 to a gate, grounding a substrate, and extracting electrons trapped by the electron trapping layer into the substrate. However, as a voltage is applied to the gate for the erase operation, back tunneling of electrons may occur in that electrons introduced between the gate and the charge trapping layer are moved from the gate to the charge trapping layer by tunneling. This back tunneling means that the electrons are provided to the charge trapping layer from the gate, which is understood as a large factor in lowering the erase efficiency. Therefore, to improve the erase efficiency, it is preferred to consider effectively preventing the electron back tunneling.

### OBJECTS AND SUMMARY

Embodiments of the present invention provide a method of manufacturing a non-volatile memory device including post-treating a gate to increase a work function of the gate that may prevent an electron back tunneling phenomenon from the gate of a transistor toward an electron trapping layer to improve an erase efficiency.

According to an aspect of embodiments of the present invention, there is provided a method of manufacturing a non-volatile memory device, the method preferably including: forming a stack structure of a tunnel dielectric layer, a charge trapping layer, a charge blocking layer and a gate on a semiconductor substrate; and performing a post treatment on the gate using an element different from the gate to increase a work function of the gate.

The term “elements” refers to elements in the form of atoms or molecules.

The tunneling dielectric layer may be approximately 2-6 nm thick.

The charge blocking layer may be a dielectric material having a dielectric constant ‘k’ of at least 7 and be approximately 3.5-[15]20 nm thick.

The gate may include a metal layer having a work function approximately ranged from 4.7 eV to 6.0 eV.

The gate may be formed of one metal selected from the group consisting of Pt, Au, TiAl alloy, Pd and Al, or formed of one selected from the group consisting of metal nitride, metal boron nitride, metal silicon nitride, metal aluminum nitride and metal silicide.

The above method may, prior to performing the post treatment of the gate, include: implanting impurity ions onto the semiconductor substrate adjacent to the gate so as to form a source region and a drain region; and annealing the source region and the drain region to activate the implanted impurity ions.

The post treatment of the gate may include surface-treating the gate using the element.

The post treatment of the gate may be performed by applying an element selected from the group consisting of N, O, F, Ne, He, P, S, Cl, Ar, As, Se, Br, Kr, Sb, Te, I and Xe to the gate.

The post treatment of the gate may include implanting the element such that the element reaches an inside of the gate or a boundary between the gate and the charge blocking layer below the gate.

The post treatment of the gate may be performed by chemically adsorbing the element on a surface of the gate.

The post treatment of the gate may be performed by applying one of the elements corresponding to group II to group VIII of the periodic table to the gate.

The post treatment of the gate may be performed by applying a halogen group element or a molecule including the halogen group element to the gate.

The post treatment of the gate may be performed by applying an electron acceptor atom or molecule to the gate.

The post treatment of the gate may include inducing the element into a plasma and providing the plasma onto the gate.

The post treatment of the gate may include forming a gas atmosphere including the element in a furnace, contacting the gas ambient with the gate, and annealing the gate or performing an RTA (Rapid Thermal Annealing) of the gate.

The annealing or the RTA may be performed at a temperature below 1000° C.

The post treatment of the gate may include chemically doping the element into the gate or coating the element on the gate.

The post treatment of the gate may include ionizing the element and ion-implanting the ionized element into the gate.

The post treatment of the gate may include exposing a surface of the gate to a chemical gas phase of the element such that the gas phase of the element interacts with the gate.

The post treatment of the gate may further comprise forming a passivation layer covering and protecting the post-treated gate.

According to another aspect of embodiments of the present invention, there is provided a non-volatile memory device preferably including: a tunnel dielectric layer disposed on a semiconductor substrate; a charge trapping layer disposed on the tunnel dielectric layer; a charge blocking layer disposed on the charge trapping layer; and a gate disposed on the charge blocking layer and including a metal layer having a work function approximately ranging from 4.7 eV to 6.0 eV.

The gate may be subjected to a post treatment to increase a work function of a material forming the gate using an element of the material forming the gate and an element different from the element of the material forming the gate.

According to embodiments of the present invention, the work function of a metal layer forming the gate is relatively further increased to prevent an electron back tunneling phenomenon from the gate toward an electron trapping layer, thereby improving an erase efficiency.

### BRIEF DESCRIPTION OF THE DRAWINGS

The above and other features and advantages of embodiments of the present invention will become more apparent by describing in detail exemplary embodiments thereof with reference to the attached drawings in which:

FIGS. 1 through 3 are sectional views schematically illustrating a non-volatile memory device and method of manufacturing the same according to embodiments of the present invention; and

FIG. 4 is a graph illustrating an erase characteristic improved by a method of manufacturing a non-volatile memory device according to embodiments of the present invention.

### DETAILED DESCRIPTION OF THE INVENTION

Embodiments of the present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

Embodiments of the present invention disclose that the gate may be configured to include a metal layer having a relatively high work function so as to prevent a back tunnelling of electrons from the gate toward an electron trapping layer during an erase operation of a non-volatile memory device, for example, a transistor including a charge trapping layer. A metal layer may be post-treated so as to further increase the work function of the metal layer.

A gate stack of a non-volatile memory device including a charge trapping layer includes a tunnel dielectric layer, a charge trapping layer, a charge blocking layer (or barrier layer) and a metal layer, which are sequentially formed on a substrate having a channel layer. At this time, the electrons may be prevented from tunnelling the charge blocking layer from a gate of the metal layer by increasing the value of a work function of the metal layer. The charge blocking layer is preferably formed of a material having a high dielectric constant ‘k’, for example, insulator. Accordingly, by considering energy bands in a junction structure of the metal layer, the insulator and the charge trapping layer, effects of increasing the work function of the metal layer may be understood.

As the design rule decreases, it is forecasted that the NAND type SONOS memory device having a line width less than 50 nm will require a programming speed of 20 μs at 17 V. Also, it is under consideration to use the operation that the threshold voltage (Vₜₕ) changes from −3 V to 1 V during a programming. This change of the threshold voltage (Vₜₕ) from −3 V to 1 V will likely require the erase speed of 2 ms at 18 V. However, it is forecasted that such a requirement for the erase speed cannot be realized by the current structure and method of the non-volatile memory device. In real circumstance, it is required to change the threshold voltage from 1 V to −3 V by applying −18 V within 2 ms, but it is very difficult for the current n-type polysilicon gate to realize such an erase speed owing to a back tunnelling phenomenon.

To solve this technical issue, embodiments of the present invention disclose forming the gate using a metal having a relatively high work function and post-treating a surface of the metal layer. When a metal layer having a work function above approximately ranging from 4.7 eV to 6.0 eV, preferably ranging from 4.9 eV to 5.1 eV, is used as a gate, it is anticipated that the above required erase speed would be satisfied. Nevertheless, it is not easy to use the metal layer having such a high work function as a gate. Also, although the metal layer having such a high work function is used as a gate, increasing the work function is advantageous in attaining the required erase speed.

By increasing an absolute value of the work function of the metal layer, a difference between a Fermi energy level (E_{F}) of the metal layer and a conduction energy level of the charge trapping layer increases relatively, and accordingly it is possible to decrease the possibility that electrons tunnel through the charge blocking layer. Accordingly, an electron back tunnelling can be suppressed.

Although the metal layer is formed of a metal having relatively a high work function, the metal layer is post-treated so as to further increase the work function of the metal layer, thereby more effectively preventing the electron back tunnelling. As the gate material forming the gate, an elementary metal group consisting of platinum (Pt), gold (Au), titanium-aluminium alloy (TiAl), palladium (Pd) and aluminium (Al), or a metal composite group consisting of metal nitride, metal boron nitride, metal silicon nitride, metal aluminium nitride and metal silicide may be considered. The work function of the metal layer formed of the aforementioned material can be increased by the post-treatment of the metal layer.

The post treatment disclosed in embodiments of the present invention may be understood in terms of concepts of chemically doping or coating atoms or molecules being high in electronegativity, to attract the electrons of the gate material. The post treatment may also be understood as ion implantation, plasma treatment, exposing the gate to a chemical gas phase, annealing the gate, etc.

At this time, elements may be adsorbed, implanted or coated in the form of atom or molecule by ion implantation, exposing the gate to a chemical gas phase, plasma treatment, etc. In the case of the post treatment using ion implantation, these elements or ions penetrate inside of the gate or a boundary between the gate and the charge blocking layer below the gate to increase the work function of the metal layer.

According to experimental results using the elements considered in the embodiments of the present invention, since electron donor atoms decrease the work function of the metal gate layer, they are not suitable. For example, the elements of group I or II in the periodic table of the elements may not be suitable for the post treatment disclosed in embodiments of the present invention. For example, annealing or plasma treatment using hydrogen gas (H₂) rather decreases the work function of the gate.

On the contrary, the halogen group or groups V to VII elements having relatively a very high reactivity in the periodic table of the elements are suitable for the post treatment disclosed in embodiments of the present invention. For example, it is measured that the plasma treatment using CF₄ gas including fluorine (F) effectively increases the work function of the metal gate layer.

Work function is generally defined as a minimum potential that the most loosely bound valence electron in a solid has to overcome so as to be released to the outer vacuum when the kinetic energy is 0 at absolute 0 degree. Accordingly, the work function can be expressed by the below equation:
eΦ=eV_{exchange}+eV_{dipole}−E_{F}

where eV_{exchange} may be a bulk value depending on a bulk electron density, eV_{dipole} may be a value depending on a surface space-charge potential.

The surface space-charge or surface dipole means an electric field affected by atoms or molecules adsorbed on a surface of a layer. Even the adsorbed inert gas atoms affect the electric field. In other words, the work function is varied by chemisorption of molecules. In an embodiment of the present invention, it is preferable that the plasma treatment of a surface of the gate be performed using relatively a high reactive gas so as to increase the work function.

In a study of embodiments of the present invention, work functions of silver (Ag) (111), copper (Cu) 100 and copper 110 are increased by a treatment using oxygen (O), work function of manganese (Mn) is increased by a surface treatment using cobalt (Co), work functions of tungsten (W) and titanium (Ti) are increased by a treatment using chloride (Cl). On the contrary, work function of copper (Cu) is decreased by a treatment using Co and work function of W is decreased by a treatment using sodium (Na) or nickel (Ni).

In considering the above study results, elements to be used for the surface treatment disclosed in embodiments of the present invention may be elements except for Group I or II elements. Preferably, the element may be B, C, Si, N, P, As, O, S, Se, Te, F, Cl, Br, In, At, Ne, Ar, Kr, Xe or Rn. Nevertheless, it is preferable that the surface treatment of the metal gate using a gas of atoms having a relatively high reactivity, for example, the halogen group elements, or a gas of atoms attracting electrons of a metal, be used among the surface treatments of the metal gate including ion implantation, annealing in a gas ambient, plasma treatment, chemical doping, and the like. Also, the metal gate may be surface-treated using non-metallic gases such as O, B, P, Sb, As, N, etc.

From the above consideration, the post treatment of the gate may be understood as a procedure increasing the work function of the gate while N, O, F, Ne, He, P, S, Cl, Ar, As, Se, Br, Kr, Sb, Te, I or Xe element acts on the gate.

In experimental results, when the surface of the metal gate is treated by a plasma treatment using Ar, it is observed that the work function increases. When the surface of the metal gate is treated by a plasma treatment using oxygen gas (O₂), it is observed that the work function increases much more than that in the plasma treatment using Ar. More, when the surface of the metal gate is treated by a plasma treatment using CF₄ gas, it is observed that the work function increases much more than that in the plasma treatment using oxygen gas.

In the case of standard samples that use a gate of Pt layer and a gate of Au and are not subjected to the post treatment disclosed in the embodiments of the present invention, it is observed that the flat band voltage (V_{FB}) of the Pt layer is about −1.768 V and the flat band voltage of the Au layer is about −2.156 V. In these cases, when their related work functions are roughly computed considering statistical parameters, the work function of the Pt layer is about 5.7 eV and the work function of the Au layer is about 5.4 eV.

Then, when the Pt layer and the Au layer are treated using hydrogen (H₂) plasma, their V_{FB} decreases to about −1.918 V and −2.406 V, respectively, which can be understood as a decrease of the work function. Also, when the Pt layer and the Au layer are treated using argon (Ar) plasma, their V_{FB} increases to about −1.554 V or slightly decreases to about −2.268 V, respectively, which can be understood as the increase or slight decrease of the work function. Accordingly, it can be understood that the effect due to the plasma treatment using the inert gas such as Ar is changed depending on the kinds of the gate layer.

In the case of oxygen plasma treatment, their measured V_{FB} values are −1.316 V and −1.876 V, respectively, which can be understood as the more effective increase of the work function. In the care of CF₄ plasma treatment, their measured V_{FB} value are −1.218V and −1.848V, which may be understood as a more effective increase of the work function. The effects according to embodiments of the present invention may be observed even in the case of using TiAl layer, Pd layer, or Al layer as the metal gate.

Thus, according to embodiments of the present invention, since the work function of the metal layer forming the gate may be effectively increased, the erase efficiency can be prevented from being degenerated by electrons tunnelling the charge blocking layer from the gate and being moved to unwanted charge trapping layer during the erase operation of the non-volatile memory device.

Embodiments of the present invention will now be described more fully with reference to the accompanying drawings, in which exemplary embodiments of the invention are shown.

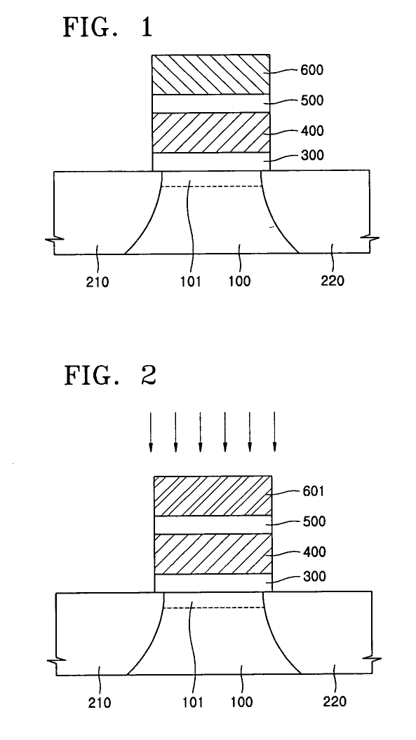

FIGS. 1 through 3 are sectional views schematically illustrating a non-volatile memory device and method of manufacturing the same according to embodiments of the present invention.

Referring to FIG. 1, a gate stack is formed according to a method of manufacturing a non-volatile memory device. For example, a tunnel dielectric layer 300 is formed on a semiconductor substrate 100, and then a charge trapping layer 400 is formed in a storage node on the tunnel dielectric layer 300. The tunnel dielectric layer 300 may be formed to a thickness of about 2-6 nm. When the non-volatile memory device is manufactured in a floating gate structure, the charge trapping layer 400 may be formed including a polysilicon layer. When the non-volatile memory device is manufactured in a SONOS structure, the charge trapping layer 400 may be formed including a silicon nitride (Si₃N₄) layer. Alternatively, the charge trapping layer 400 may be formed as a type of quantum dot or nanocrystal dot or silicon oxynitride.

After the charge trapping layer 400 is formed, a gate 600 is formed on the charge trapping layer 400. Though the gate may be formed of one of various conductive materials, it is preferable that the gate be formed including a metal layer having relatively a high work function. For example, the gate 600 may be formed of Pt layer, Au layer, Pd layer, TiAl layer, Al layer, or their composite layers.

A charge blocking layer 500 is formed at a boundary between the gate 600 and the charge trapping layer 400. The charge blocking layer 500 is interposed between the gate 600 and the charge trapping layer 400 so as to block charges such as electrons from being moved from the gate 600 to the charge trapping layer 400, or vice versa. The charge blocking layer 500 may be formed of a dielectric material having a high dielectric constant (k), for example, oxide layer. The charge blocking layer 500 may be 3.5-20 nm thick. It may be understood that the dielectric material having a high dielectric constant (k) is a material having a higher dielectric constant than a general silicon oxide.

After the stack structure of the above layers is formed, these layers are patterned to form a gate stack. The patterning can be performed by forming a hard mask, for example, a silicon nitride layer pattern, on the gate and performing a dry etch using the hard mask as an etch mask. At this time, the patterning may be performed such that the gate has a line width below about 50 nm. The gate stack may be formed in a shape to realize a NAND type SONOS memory device having the line width below 50 nm.

After the gate stack is formed as above, a source region 210 and a drain region 220 that define a channel 101 are formed at both sides of the semiconductor substrate 100 adjacent to the gate 600. For example, the source and drain regions 210 and 220 are formed by selectively ion-implanting impurity ions into the semiconductor substrate 100. Then, the resultant substrate 100 may be annealed to activate the source and drain regions 210 and 220. For example, the resultant substrate 100 may be annealed at a high temperature of about 1000-1100° C. to activate the source and drain regions 210 and 220.

Referring to FIG. 2, in order to further increase the work function of the metal layer forming the gate (see 600 of FIG. 1) a post-treatment of the gate 601 is performed, so that the work function of the gate 601 as post-treated further increases. The post treatment of the gate can be substantially understood as the surface treatment of the metal layer. Also, the post treatment may be performed by various processes used for manufacturing semiconductor devices.

For example, the post treatment may be performed by an ambient thermal treatment in which an ambient is formed on the gate 601 and then the gate is annealed. At this time, the ambient thermal treatment may be performed in a general furnace or a rapid thermal annealing (RTA) furnace. Alternatively, the post treatment of the gate may be performed by a plasma treatment using a reactive gas, a chemical doping, a coating or the like. In addition, the post treatment may be performed by ion implantation or exposing a surface of the gate to a chemical vapor. Further, the post treatment may be performed using a tool for the diffusion process.

When the post treatment of the gate 601 in 6-inch wafer is performed by plasma, source power may be about 50-200 W and the post treatment may be performed for 30 seconds to 2 minutes.

Meanwhile, the post treatment for increasing the work function of the metal layer constituting the gate 601 can use various elements different than the element of the material forming the gate 601. Nevertheless, since electron donor atoms decrease the work function of the metal layer forming the gate 601, they may be not suitable for the post treatment. For example, thermal treatment or plasma treatment using hydrogen gas (H₂) may rather decrease the work function of the gate.

The elements for the post treatment of the gate may be used in a gas state of atoms or molecules. In particular, the electron acceptor atoms are useful, and a highly reactive gas, such as the halogen group elements having a high electronegativity, may be used as an ambient or plasma source for the post treatment. In addition, ion implantation using a compound including the halogen group element as ion source may be possible. Meanwhile, non-metallic gas, such as oxygen gas, can be also used as the ambient, plasma source, or ion source. In particular, it is confirmed that the plasma treatment using oxygen gas and CF₄ as the plasma source gases increases the work function of the gate. Of course, it is also confirmed that the plasma treatment using the inert gas, such as Ar, increases the work function of the gate, though the increase of the work function is relatively a low value.

After the post treatment of the metal layer forming the gate 601 is performed to increase the work function of the gate 601, subsequent processes for forming a general transistor are performed. Meanwhile, while the post treatment is performed, the source and drain regions 210 and 220 are selectively shielded and protected from the post treatment. For this purpose, an insulating layer (not shown) or a mask may be introduced.

Referring to FIG. 3, a process for forming a passivation layer 700 covering and protecting the upper and side surfaces of the gate 601 that is subjected to the post treatment to increase the work function will be described. By the post treatment, the elements different the metal layer of the gate 601 are substantially chemically adsorbed on the upper and side surfaces of the gate 601. Accordingly, to keep the elements adsorbed on the upper and side surfaces of the gate 601 in the chemisorption state, the passivation layer 700 covering the upper and side surface of the gate 601 is formed. The passivation layer 700 may be formed of an insulator such as oxide or nitride to suppress the atoms, molecules or ions adsorbed on the upper and side surfaces of the gate, implanted or diffused into the inside or boundary from evaporating or being desorbed.

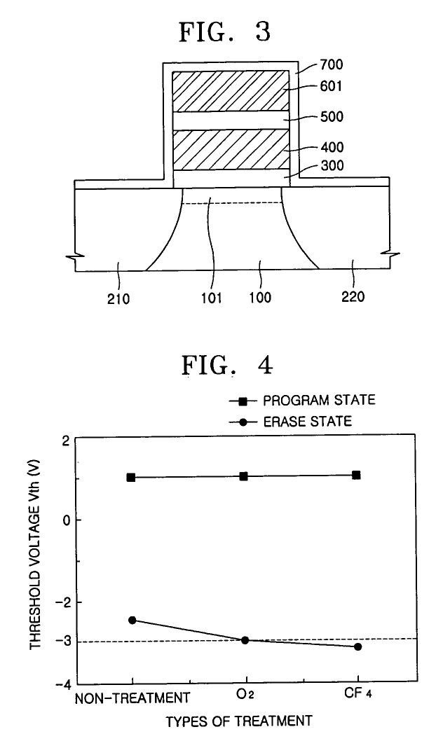

FIG. 4 is a graph illustrating an erase characteristic improved by a method of manufacturing a non-volatile memory device according to embodiments of the present invention.

Specifically, FIG. 4 shows threshold voltages (Vₜₕ) measured in a program operation and an erase operation using a sample that a layer of SiO₂/SiN/Al₂O₃ is formed below a metal gate at a thickness of 32 Å/63 Å/140 Å. As shown in FIG. 4, the sample that is subjected to plasma treatment of the gate using oxygen gas reaches a lower threshold voltage than the sample that is not subjected to the post treatment of the gate. Also, the sample that is subjected to the plasma treatment of the gate using CF₄ gas reach a very lower threshold voltage at the erase state. At this time, the bias for the erase operation is −18 V and the time interval for the erase operation is 2 ms.

It is forecasted that the present NAND type SONOS memory device having the line width less than 50 nm will require 2 ms of erase speed for changing the threshold voltage (Vₜₕ) from 1 V to −3 V of 2 ms at the bias of −18 V. Accordingly, as shown in FIG. 4, when the metal gate layer according to embodiments of the present invention is post-treated, it is possible to decrease the threshold voltage below −3 V while keeping the erase time at 2 ms. Accordingly, like in the NAND type SONOS memory device having the line width less than 50 nm, it is possible to realize the non-volatile memory device having the reduced design rule.

According to embodiments of the present invention, since the gate is formed of a metal layer having a relatively high work function and then the metal layer is post-treated, the gate can have a higher work function. Accordingly, the electron back tunnelling recognized as a factor decreasing the erase efficiency can be suppressed. Accordingly, under the bias voltage of about −18 V, it is possible to decrease the threshold voltage (Vₜₕ) from the program state of 1 V to the erase state of −3 V within the erase time of 2 ms. Accordingly, non-volatile memory device having reduced design rule and being operable at a low power can be realized.

While embodiments of the present invention have been particularly shown and described with reference to exemplary embodiments thereof, it will be understood by those of ordinary skill in the art that various changes in form and details may be made therein without departing from the spirit and scope of embodiments of the present invention as defined by the following claims.

What is claimed is:

1. A method of manufacturing a non-volatile memory device, the method comprising:
forming a stack structure of a tunnel dielectric layer, a charge trapping layer, a charge blocking layer and a gate comprising an element on a semiconductor substrate; and
performing a post treatment on the gate using an element different from the element of the gate to increase a work function of the gate.

2. The method of claim 1, wherein the tunneling dielectric layer is 2 to 6 nm thick.

3. The method of claim 1, wherein the charge blocking layer comprises a dielectric material having a dielectric constant of at least 7 and is 3.5 to 20 nm thick.

4. The method of claim 1, wherein the gate comprises a metal layer having a work function ranging from 4.7 eV to 6.0 eV.

5. The method of claim 1, wherein the gate comprises an element selected from the group consisting of Pt, Au, TiAl alloy, Pd and Al, or an element selected from the group consisting of metal nitride, metal boron nitride, metal silicon nitride, metal aluminum nitride and metal silicide.

6. The method of claim 1, further comprising, prior to performing the post treatment of the gate:
implanting impurity ions onto the semiconductor substrate adjacent to the gate so as to form a source region and a drain region; and
annealing the source region and the drain region.

7. The method of claim 1, wherein the post treatment of the gate comprises surface-treating the gate using the element different from the element of the gate.

8. The method of claim 1, wherein the post treatment of the gate comprises implanting the element different from the element of the gate such that the element reaches an inside of the gate or a boundary between the gate and the charge blocking layer below the gate.

9. The method of claim 1, wherein the post treatment of the gate comprises chemically adsorbing the element different from the element of the gate on a surface of the gate.

10. The method of claim 1, wherein the post treatment of the gate comprises applying at least one element corresponding to group II to group VIII of the periodic table to the gate.

11. The method of claim 1, wherein the post treatment of the gate comprises applying a halogen group element or a molecule including the halogen group element to the gate.

12. The method of claim 1, wherein the post treatment of the gate comprises applying an electron acceptor atom or molecule to the gate.

13. The method of claim 1, wherein the post treatment of the gate comprises applying an element selected from the group consisting of N, O, F, Ne, He, P, S, Cl, Ar, As, Se, Br, Kr, Sb, Te, I and Xe to the gate.

14. The method of claim 1, wherein the post treatment of the gate comprises inducting the element different from the element of the gate into a plasma and providing the plasma onto the gate.

15. The method of claim 1, wherein the post treatment of the gate comprises forming a gas atmosphere including the element different from the element of the gate in a furnace, contacting the gas ambient with the gate, and annealing the gate or performing rapid thermal annealing of the gate.

16. The method of claim 15, wherein the annealing or the rapid thermal annealing is performed at a temperature below 1000° C.

17. The method of claim 1, wherein the post treatment of the gate comprises chemically doping the element different from the element of the gate into the gate or coating the element different from the element of the gate on the gate.

18. The method of claim 1, wherein the post treatment of the gate comprises ionizing the element different from the element of the gate different from the element of the gate and ion-implanting the ionized element into the gate.

19. The method of claim 1, wherein the post treatment of the gate comprises exposing a surface of the gate to a chemical gas phase of the element different from the element of the gate such that the gas phase of the element interacts with the gate.

20. The method of claim 1, further comprises, after the post treatment of the gate:
forming a passivation layer on the post-treated gate.

21. A method of manufacturing a non-volatile memory device, the method comprising:
forming a stack structure of a tunnel dielectric layer, a charge trapping layer, a charge blocking layer and a gate a semiconductor substrate; and
treating a surface of the gate using an oxygen plasma to increase a work function of the gate.

22. A method of manufacturing a non-volatile memory device, the method comprising:
forming a stack structure of a tunnel dielectric layer, a charge trapping layer, a charge blocking layer and a gate on a semiconductor substrate; and
treating a surface of the gate using a plasma of a gas comprising at least one of the halogen group elements to increase a work function of a element forming the gate.

23. The method of claim 22, wherein the gas comprising at least one of the halogen group elements is CF₄.

24. A method of manufacturing a non-volatile memory device, the method comprising:
forming a stack structure of a tunnel dielectric layer, a charge trapping layer, a charge blocking layer and a metal gate on a semiconductor substrate;
treating a surface of the gate using a plasma of a gas comprising an oxygen gas or one of the halogen group elements to increase a work function of the metal gate; and
forming a passivation layer on a surface of the metal gate whose surface is treated.

25. A method of manufacturing a non-volatile memory device, the method comprising:
forming a stack structure of a tunnel dielectric layer, a charge trapping layer, a charge blocking layer and a metal gate on a semiconductor substrate;
implanting ions of oxygen or one of the halogen group elements into the metal gate to increase a work function of the gate; and
forming a passivation layer on a surface of the metal gate into which the ions are implanted.

26. A non-volatile memory device comprising:
a tunnel dielectric layer disposed on a semiconductor substrate;
a charge trapping layer disposed on the tunnel dielectric layer;
a charge blocking layer disposed on the charge trapping layer; and
a gate disposed on the charge blocking layer and comprising a metal layer having a work function ranging from 4.7 eV to 6.0 eV.

27. The non-volatile memory device of claim 26, wherein the gate is subject to a post treatment to increase a work function of an element forming the gate using an element different from the element forming the gate.

28. The non-volatile memory device of claim 26, wherein the tunneling dielectric layer is 2 to 6 nm thick.

29. The non-volatile memory device of claim 26, wherein the charge blocking layer comprises a dielectric material having a dielectric constant of at least 7 and is 3.5 to 15 nm thick.

30. The non-volatile memory device of claim 1, wherein the gate comprises an element selected from the group consisting of Pt, Au, TiAl alloy, Pd and Al, or comprises an element selected from the group consisting of metal nitride, metal boron nitride, metal silicon nitride, metal aluminum nitride and metal silicide.

31. A non-volatile memory device comprising:
a tunnel dielectric layer disposed on a semiconductor substrate;
a charge trapping layer disposed on the tunnel dielectric layer;
a charge blocking layer disposed on the charge trapping layer; and
a gate disposed on the charge blocking layer and post treated by using an element different from an element of the gate to increase a work function of the gate.

32. The non-volatile memory device of claim 31, wherein the gate comprises an element selected from the group consisting of Pt, Au, TiAl alloy, Pd and Al, or comprises an element selected from the group consisting of metal nitride, metal boron nitride, metal silicon nitride, metal aluminum nitride and metal silicide.

33. The non-volatile memory device of claim 31, wherein the element used in the post treatment comprises an element selected from the group consisting of N, O, F, Ne, He, P, S, Cl, Ar, As, Se, Br, Kr, Sb, Te, I and Xe.
